(19) United States
(12) Patent Application Publication
(10) Pub. No.: US 2026/0231324 A1
(43) Pub. Date: Aug. 6, 2026

(54) Metallic Paste for Ceramic Substrate

(71) Applicant: CeramTec GmbH, Plochingen (DE)

(72) Inventors: Roland Leneis, Marktredwitz (DE); Klaus Herrmann, Thiersheim (DE); Alfred Thimm, Wunsiedel (DE); Katharina Härtl, Thiersheim (DE); Daniela Meyer, Regensburg (DE)

(21) Appl. No.: 19/154,900

(22) PCT Filed: Jan. 24, 2024
(86) PCT No.: PCT/EP2024/051578

§ 371 Date: Aug. 8, 2025

(30) Foreign Application Priority Data
Feb. 9, 2023 (EP) 23155817.2
Mar. 3, 2023 (EP) 23159858.2
Nov. 22, 2023 (EP) 23211400.9

(51) Int. Cl. H05K 1/09; H01B 1/22; H05K 1/03; H05K 3/12

(52) U.S. Cl. CPC H05K 1/092; H01B 1/22; H05K 1/0306; H05K 3/1291; H05K 2201/0209; H05K 2201/0239; H05K 2203/1131

(57) ABSTRACT

Provided is a metallic paste for a ceramic substrate comprising a metallic alloy Ni—Cu—Fe powder, Glass powder, and further additives.

### CROSS-REFERENCE TO RELATED APPLICATIONS

This application is the United States national phase of International Patent Application No. PCT/EP2024/051578 filed Jan. 24, 2024 and claims priority to European Patent Application Nos. 23155817.2 filed Feb. 9, 2023, 23159858.2 filed Mar. 3, 2023, and 23211400.9 filed Nov. 22, 2023, the disclosures of each of which are hereby incorporated by reference in their entireties.

### BACKGROUND

### Technical Field

The present disclosure relates to a metallic paste, a method for obtaining the same and its use.

### Technical Considerations

Substrates made of a ceramic, such as alumina (Al₂O₃) or aluminium nitride (AlN), are commonly used as circuit substrates for various electronic components. As one of the methods for forming the circuit (a conductor or metal layer) on such as a ceramic substrate, a conductor or metallic paste is used to form the electric circuit though the process of screen printing, drying and firing.

The conductor or metallic paste is generally one in which a conductive powder and a glass powder are dispersed in an organic medium.

Different metallic pastes have been described in the past. For example, EP 2 164 822 B1 discloses a conductor paste for ceramic substrates comprising a) a conductive metal powder comprising silver and palladium; b) a glass powder; and c) an organic solvent, wherein the conductive metal powder has an average particle diameter of not more than 1.2 μm, and the glass powder is a Bi₂O₃—SiO₂—B₂O₃ type glass powder, and a content of the glass powder is in a range of from 1 to 6 wt % based on the weight of the paste. The paste as described in EP 2 164 822 B1 allows sintering of the paste applied to the ceramic substrate at temperatures of not more than 650° C. and shows at the same time excellent adhesive strength on a ceramic substrate. However, the paste uses silver and palladium that are rather expensive materials hampering the use of such a paste in mass production.

WO 2014/195097 A1 describes a metal coating on a ceramic substrate. The metal coating is obtained by applying a metallic paste on the ceramic substrate and subsequent sintering. The paste may comprise Ni powder, Fe powder, Cu powder, glass powder MnO—SiO₂—Al₂O₃ and an organic solvent. The Fe powder may be replaced at least partially by Ti powder and/or Al powder. Another glass powder described is made of ZnO—SiO₂—B₂O₃—Al₂O₃—TiO₂—ZrO₂. The metallic paste is sintered at temperatures between 800-900° C., preferably between 830-870° C. However, it turned out that sintering temperature and sintering time are not optimal when using such a paste.

### SUMMARY

It was therefore an object of the present disclosure to provide a metallic paste for ceramic substrates that has optimal sintering temperatures and sintering times and is at the same time weldable, solderable and bondable without further processing, shows oxidation resistant after sintering, as well as ferro- or paramagnetic properties and/or is electrically conductive.

This object was solved by a metallic paste with features as described herein.

Accordingly, a metallic paste for a ceramic substrate is provided that comprises:
a metallic alloy Ni—Cu—Fe powder,
Glass powder, and
further additives.

The metallic paste according to the present disclosure combines several properties. Iron-nickel alloys are used in the chemical industry because of their catalytic properties and due to their mechanical, thermal or magnetic properties. Copper-nickel alloys are often used in shipbuilding due to their high resistance to corrosion and seawater erosion. In addition, these copper-nickel alloys have inherent antifouling properties. In a Ni—Cu—Fe alloy, as in the present case, both advantages are combined.

In some non-limiting embodiments of the present paste, 60-80 wt % preferably 65-76 wt %, more preferably of 68-73 wt % (based on the overall weight of the paste) of the Ni—Cu—Fe powder are used.

In some non-limiting embodiments, the present paste may comprise additionally Fe powder and/or Ni powder and/or Titan (IV) oxide (titanium (IV) oxide).

Thus, in some non-limiting embodiments, the paste comprises 0.0-5 wt %, preferably 1-4 wt %, more preferably 1.2-3 wt %, (based on the overall weight of the paste) Fe powder.

In some non-limiting embodiments, 0.0-5 wt %, preferably 1-4 wt %, more preferably 1.2-3 wt %, (based on the overall weight of the paste) Ni powder are added.

In some non-limiting embodiments, the paste comprises 0.0-10 wt %, preferably 1-8 wt %, more preferably 1.2-5 wt %, (based on the overall weight of the paste) TiO₂.

In some non-limiting embodiments, 3-15 wt %, preferably 5-10 wt %, more preferably 6-8 wt % (based on the overall weight of the paste) glass powder are comprised into the paste.

Further additives may be added in an amount of 15-25 wt % of further additives.

In some non-limiting embodiments, the metallic paste has the following composition:
60-80 wt %, preferably 65-76 wt %, more preferably of 68-73 wt % (based on the overall weight of the paste) of the Ni—Cu—Fe powder,
0.0-5 wt %, preferably 1-4 wt %, more preferably 1.2-3 wt %, (based on the overall weight of the paste) Fe powder;
0.0-5 wt %, preferably 1-4 wt %, more preferably 1.2-3 wt %, (based on the overall weight of the paste) Ni powder;
0.0-10 wt %, preferably 1-8 wt %, more preferably 1.2-5 wt %, (based on the overall weight of the paste) TiO₂;
3-15 wt %, preferably 5-10 wt %, more preferably 6-8 wt % (based on the overall weight of the paste) glass powder; and
15-25 wt % of further additives, wherein the sum of all ingredients always adds up to 100 wt %.

In some non-limiting embodiments, the metallic paste has the following composition:
60-80 wt % (based on the overall weight of the paste) of the Ni—Cu—Fe powder,
0.0-5 wt % (based on the overall weight of the paste) Fe powder;
0.0-5 wt % (based on the overall weight of the paste) Ni powder;
0.0-10 wt % based on the overall weight of the paste) TiO₂;
3-15 wt % (based on the overall weight of the paste) glass powder; and
15-25 wt % of further additives, wherein the sum of all ingredients always adds up to 100 wt %.

In some non-limiting embodiments, the metallic paste has the following composition:
65-76 wt % (based on the overall weight of the paste) of the Ni—Cu—Fe powder,
1-4 wt % (based on the overall weight of the paste) Fe powder;
1-4 wt % (based on the overall weight of the paste) Ni powder;
1-8 wt % (based on the overall weight of the paste) TiO₂;
5-10 wt % (based on the overall weight of the paste) glass powder; and
15-25 wt % of further additives, wherein the sum of all ingredients always adds up to 100 wt %.

In some non-limiting embodiments, the metallic paste has the following composition:
68-73 wt % (based on the overall weight of the paste) of the Ni—Cu—Fe powder,
1.2-3 wt %, (based on the overall weight of the paste) Fe powder;
1.2-3 wt %, (based on the overall weight of the paste) Ni powder;
1.2-5 wt %, (based on the overall weight of the paste) TiO₂;
6-8 wt % (based on the overall weight of the paste) glass powder; and
15-25 wt % of further additives, wherein the sum of all ingredients always adds up to 100 wt %.

As will be discussed further below in more detail, the further additives (inorganic and organic) may comprise SiO₂, a binder, a dispersant (e.g. a polymer ester), a solvent and/or a diluent.

The metallic paste of the disclosure can be sintered at temperatures from 650° C. to 1600° C., preferably from 800° C. to 1500° C., most preferably from 900° C. to 1400° C. for 30 min and up to 12 hrs., preferably less than 10 hrs., most preferably less than 8 hrs.

The sintering occurs in an inert or reducing atmosphere, preferably in a reducing atmosphere. The reducing atmosphere may comprise hydrogen and a further inert gas, such as a mixture of hydrogen and nitrogen, preferably a mixture up to 50 parts hydrogen and 50 parts nitrogen. The reducing atmosphere is preferred over an oxidizing atmosphere.

Due to these sintering parameters, the metallic paste is characterized by a good adhesion on ceramic parts, good electrical conductivity and/or good paramagnetic properties. Ceramic parts may be substrates or carriers for printed circuit boards or any other ceramic component, such as three-dimensional components.

### Ni—Cu—Fe Alloy Powder

The Ni—Cu—Fe alloy powder provides magnetic properties and enables bonding, soldering, welding of the metallic paste.

In some non-limiting embodiments, the Ni—Cu—Fe alloy powder comprises 15-35 wt % (based on the overall weight of the Ni—Cu—Fe alloy powder), preferably 18-30 wt %, most preferably 20-28 wt % Ni,

In some non-limiting embodiments, the Ni—Cu—Fe alloy powder comprises 12-26 wt % (based on the overall weight of the Ni—Cu—Fe alloy powder), preferably 15-25 wt-%, most preferably 18-23 wt % Cu.

In some non-limiting embodiments, Ni—Cu—Fe alloy powder comprises 45-75 wt % (based on the overall weight of the Ni—Cu—Fe alloy powder), preferably 50-70 wt %, most preferably 55-65 wt % Fe,

In some non-limiting embodiments, the Ni—Cu—Fe alloy powder comprises:
15-35 wt % Ni, preferably 18-30 wt % Ni, most preferably 20-28 wt % Ni,
12-26 wt % Cu, preferably 15-25 wt % Cu, most preferably 18-23 wt % Cu, and
45-75 wt % Fe, preferably 50-70 wt % Fe, most preferably 55-65 wt % Fe,
based on the overall weight of the Ni—Cu—Fe alloy powder. Preferably, the sum of all ingredients always adds up to 100 wt %.

In some non-limiting embodiments, the Ni—Cu—Fe alloy powder comprises 15-35 wt % Ni, 12-26 wt % Cu, and 45-75 wt % Fe based on the overall weight of the Ni—Cu—Fe alloy powder. Preferably, the sum of all ingredients always adds up to 100 wt %.

In some non-limiting embodiments, the Ni—Cu—Fe alloy powder comprises 18-30 wt % Ni, 15-25 wt % Cu, and 50-70 wt % Fe based on the overall weight of the Ni—Cu—Fe alloy powder. Preferably, the sum of all ingredients always adds up to 100 wt %.

In some non-limiting embodiments, the Ni—Cu—Fe alloy powder comprises 20-28 wt % Ni, 18-23 wt % Cu and 55-65 wt % Fe based on the overall weight of the Ni—Cu—Fe alloy powder. Preferably, the sum of all ingredients always adds up to 100 wt %.

The alloy powder is obtained by mixing each of the metals, melting the mixture and spraying the melt through a jet (preferably a laval jet) to obtain a powder. The melt flows through the jet, wherein the melt is surrounded by an inert gas stream with the same flow direction.

The average particle size d90 of the Ni—Cu—Fe powder is about 3-60 μm, preferably about 5-50 μm, more preferably about 8-40 μm, most preferably about 10-18 μm. The average particle size d50 of the Ni—Cu—Fe powder is about 1-40 μm, preferably about 2-30 μm, more preferably about 4-20 μm, most preferably 4-12 μm (determined according to ISO 13320 using Cilas 1064 Lasergranulometer).

When using a Ni—Cu—Fe alloy powder it is possible to reduce the sintering time and temperature in comparison to the use of separate metal powders, such as Ni—, Fe— or Cu— powder.

### Further Metal Powders

As mentioned above besides the Ni—Cu—Fe alloy powder further metal powders may be added.

The Fe powder enables bonding, soldering, welding of the metallic paste.

The average d50 particle size of the Fe powder is 0.5-20 μm, preferably 2-15 μm, more preferably 4-12 μm, most preferably 7-12 μm (determined according to ISO 13320 using Cilas 1064 Lasergranulometer).

The Ni powder enables bonding, soldering, welding of the metallic paste.

The Ni powder has a grain size of d50 of 3-20 μm, preferably 5-18 μm, most preferably 8-15 μm and preferably a grain size of d99 of below 90 μm and preferably below 80 μm (determined using Cilas 1064 Lasergranulometer, according to ISO 13320).

However, it is to be understood that the present paste may also be free of any additional Fe powder and/or Ni-powder.

TiO₂ improves the adhesion of the metallic paste on the ceramic substrate. Furthermore, the use of TiO₂ instead of Ti is more cost efficient.

### Glass Powder

Glass is used for generating and improving adhesion of the metallic paste to the ceramic substrate. Glass also contributes to lowering the surface energy of the melted paste.

The presently used glass powder is based on a Zn—Si—B—O glass. Specifically, the glass powder comprises ZnO, SiO₂, B₂O₃. Preferably the amount of ZnO, SiO₂ and B₂O₃ is between 60-95 wt %, more preferably 75-90 wt %. The glass may further comprise TiO₂, ZrO₂ Li₂O, Na₂O, CaO, Al₂O₃, or a mixture thereof.

In some non-limiting embodiments the glass powder may comprise 25-45 wt %, preferably 30-35 wt % ZnO, 10-30 wt %, preferably 15-20 wt % B203, 20-40 wt %, preferably 25-35 wt % SiO₂, and further oxides such as TiO₂, ZrO₂, Li₂O, Na₂O, CaO, and/or Al₂O₃. The sum of all ingredients always adds up to 100 wt %. In some non-limiting embodiments each of the compounds TiO₂, ZrO₂, Li₂O, Na₂O, CaO, and/or Al₂O₃ may be added in an amount between 0-7 wt %.

The glass melts at temperatures below 1500° C., preferably below 1200° C., most preferably below 1000° C. The glass powder melts at a lower temperature by maintaining its properties.

The average particle size d50 is 0.5-10 μm, preferably 0.8-8 μm, more preferably 1.0-5 μm (determined according to ISO 13320 using Cilas 1064 Lasergranulometer). This particle size of the glass powder provides an optimal printability and sintering activity.

The glass powder in the paste may also be mixed with two or more types of glass powders used in combination.

It is to be noted that the present metal paste does not comprise or contain any (noteworthy) amount of aluminum Al. Only trace of Al of less than 1.3 wt % can be present in the glass powder. The addition of Al is indeed not desirable, since Al impairs the properties of the paste, either due to unfavorable properties of Al in the paste or due to reaction of Al with other compounds of the paste. Besides, Al impairs the magnetic properties of the paste.

Furthermore, CuO or CuO₂ are not added to the paste as the short sintering time is not sufficient to reduce the oxide completely to the metal thus leading to disorders in the sintering and soldering process. Tungsten W/tungsten oxide WO₂, molybdenum Mo, tantalum Ta are not added to the paste, since the metals increase the melting point. The paste is free of lead Pb.

As mentioned above, further additives may be comprised in the metal paste.

### Solvent/Diluent

A solvent and/or diluent is added for adjusting the viscosity of the metallic paste for subsequent application, for example for application on ceramic substrates or carriers for printed circuit boards or any other ceramic component, such as three-dimensional components. The metallic paste can be applied to a substrate or carriers for printed circuit boards or any other ceramic component, such as three-dimensional components by different printing techniques, spraying the paste onto a substrate or carriers for printed circuit boards or any other ceramic component, such as three-dimensional components or by diving the substrate into the paste. The solvent and/or diluent is removed after application during the drying and sintering process.

There are no limitations on the type of the organic solvent/diluent. Examples of the organic solvent/diluent comprise, but are not limited to, α-terpineol, butyl carbitol, butyl carbitol acetate, Texanol, octanol, 2-ethylhexanol, and/or mineral spirit. The preferred solvents/diluents are α-terpineol, butyl carbitol, butyl carbitol acetate, Texanol, octanol, 2-ethylhexanol, and/or mineral spirit.

The amount of solvent/diluent in the paste is 0.5-15 wt %, preferably 1.0-11.0 wt %, more preferably 1.5-8.0 wt %.

SiO₂, in amorphous and/or crystalline form, acts as a thickener and is responsible for the thixotropic properties of the metal paste. SiO₂ may be added in an amount of 0.1-1 wt %, preferably 0.15-0.8 wt %, more preferably 0.18-0.6 wt %.

In some non-limiting embodiments, fumed silica may be used. Fumed silica is a synthetically produced, colloidal material with defined properties and particle size, which is used as a filler in plastics. It consists entirely of amorphous silicon dioxide particles (SiO₂), which are aggregated into larger units. The primary particle size of fumed silica is about 5-50 nm with a specific BET surface of 50-600 m²/g. The aggregate size is 0.1-100 μm.

A binder is used for providing the paste-like consistency and the basic viscosity of the paste. The binder may consist of an organic liquid with a low volatility like short (C10), middle (C50) or long (C100) chain ethers and/or esters, carboxylic acids, fatty acids, and/or cyclic and non-cyclic, linear or branched polyether or polyester, preferably with O as hetero atom in the chain. The binder may also be a mixture of a polymer powder dissolved in a suitable solvent or a resin dissolved in a solvent. Examples of suitable polymers are polymethacrylates or Nitrocellulose, both linear or branched, but not limited to those. Examples of such resins comprise an ethyl cellulose resin, a hydroxypropyl cellulose resin, an acrylic resin, a polyester resin, a polyvinyl butyral resin, a polyvinyl alcohol resin, a rosin-modified resin, and/or an epoxy resin.

The binder may be added in an amount of 10-20 wt %, preferably 12-18 wt %, more preferably 13-16 wt %.

A dispersant (e.g., a polymer ester) is used for improving the mixing of all paste components. The dispersant may be added in an amount of 0.1-0.3 wt %, preferably 0.12-0.2 wt %, more preferably 0.13-0.18 wt %.

The metallic paste is obtained in a method comprising the steps of
mixing metallic alloy Ni—Cu—Fe powder, optionally Fe powder, optionally Ni powder, optionally Titan (IV) oxide, Glass powder, and SiO₂ to provide a first mixture,
adding organic additives, for example solvent, binder and dispersant to the first mixture for adjusting viscosity,
blending the mixture until a (smooth) paste is obtained.

The compounds of the paste are provided in the amounts as described above.

The compounds of the paste are blended or mixed in a suitable blending or mixing device. The rotational speed of the mixing device should be adjusted such that the paste is preferably not heated in the mixing process.

As previously mentioned, the metallic paste is used as a conductor layer on ceramic parts, such as a ceramic substrate for circuit boards, on cooling devices or 3D elements.

A suitable ceramic substrate can be oxide ceramics such as Al₂O₃, Al₂O₃—ZrO₂, Al₂O₃—SiO₂, Al₂O₃/ZrO₂/Y₂O₃ and/or ZrO₂, non-oxide ceramics like AlN and/or Si₃N₄, but also dielectric or magnetic materials.

The present metallic paste is applied to the ceramic substrate, and subsequently sintered at a temperature of more than 650° C., preferably more than 800° C., most preferably more than 900° C.

As mentioned previously, the metallic paste according to the disclosure is used to form an electric circuit on the ceramic substrate. For this purpose, a solder is applied onto the sintered metallic paste on the ceramic substrate. It has been shown that the present metallic paste has a high wettability, i.e., the solder can be applied very well to the paste and remains on it; and a high resistance to removal, i.e., the solder does not remove the paste from the ceramic (i.e., preferably 95% of the paste should remain on the ceramic compound).

The specific square resistance of a conductor track applied to the ceramic is between 100-220 mOhm/sq, preferably between 120-200 mOhm/sq. The square resistance can be adjusted by adapting the sintering conditions.

### DETAILED DESCRIPTION

The solution is now explained in more detail with reference to the examples.

The following examples are included to demonstrate certain aspects and embodiments of the disclosure as described herein. It should be appreciated by those of skill in the art, however, that the following description is illustrative only and should not be taken in any way as a restriction of the disclosure.

Non-limiting embodiments of the metallic paste according to the disclosure may have the following composition:

| | | Amount [wt %] - | Amount [wt %] - |
|---|---|---|---|
| | | 1st embodiment | 2nd embodiment |
| | Compound | Screen printing | Diving |
| 1 | Metal powder N—Cu—Fe | 68-73 | 68-73 |
| 2 | Iron powder | 0.0-3.0 | 0.0-3.0 |
| 3 | Nickel powder | 0.0-3.0 | 0.0-3.0 |
| 4 | Titanium(IV) oxide | 0.0-5.0 | 0.0-5.0 |
| 5 | Glass powder | 6-8 | 6-8 |
| 6 | Thickener | 0.18-0.6 | 0.18-0.6 |
| 7 | Binder | 13-16 | 13-16 |
| 8 | Dispersant | 0.13-0.18 | 0.13-0.18 |
| 9 | Solvent/diluent | 1.5-3.0 | 3.0-8.0 |

### Components and Amounts Sorted by Inorganic Ingredients and Organic Ingredients:

| | Compound | Amount [wt %] |
|---|---|---|
| | Inorganic ingredients | 70-90 |
| 1 | Metal powder | 84-87 |
| 2 | Iron powder | 0.0-2.0 |
| 3 | Nickel powder | 0.0-2.0 |
| 4 | Titanium(IV)-oxide | 0.0 5.0 |
| 5 | Glass powder | 6-10 |
| 6 | Thickener | 0.18-0.6 |
| | Organic ingredients | 10-30 |
| 7 | Binder | 85-95 |
| 8 | Dispersant | 4-10 |
| 9 | Solvent/diluent | 1-15 (8-10 for diving |
| | | paste, 2-4 for screen |
| | | printing |

The sum of all ingredients always adds up to 100 wt %.

The particle sizes of the different compounds used in the paste are in each case determined according to ISO 13320 using Cilas 1064 Lasergranulometer.

### Preparation of NCF Paste:

The metallic alloy Ni—Cu—Fe powder was obtained by mixing each of the metals, melting the mixture and granulating to obtain a powder. The metallic paste is obtained in a method comprising the steps of
mixing metallic alloy Ni—Cu—Fe powder, optionally Fe powder, optionally Ni powder, optionally Titan (IV) oxide, Glass powder, and SiO₂ to provide a first mixture,
adding organic additives, for example solvent, binder and dispersant to the first mixture for adjusting viscosity,
blending the mixture until a (smooth) paste is obtained.

The compounds of the paste are provided in the amounts as described in the table above.

### Wettability of the Metallic Paste

A ceramic on which the paste is baked is immersed in a solder bath at at least 250° C. The solder bath comprises a solder made of tin/silver/copper, lead-free: The ceramic remains in the bath for approx. 10 seconds and is then pulled out: when it is pulled out for the first time, it is determined how much solder “sticks” to the paste, the more the higher the wettability. After removal from the solder bath, more than 80% of the fired paste is wetted.

### Solder Leach Resistance

In order to determine the solubility of the metallization in the solder, the ceramic is dipped several times and it is checked after several passes whether paste is still attached to the ceramic. It is undesirable that the baked paste forms its own alloy with the solder and/or detaches. In these experiments, the paste according to the disclosure does not/barely react with the solder and more than 80% remains on the ceramic.

The adhesive strength of the metallic paste is more than >5N/mm². The adhesion strength provides information of how strongly the metallization is bonded to the ceramic. Nuts are attached to the metallization (with glue if the metallization is not solderable, with solder if it is) and then subjected to tensile stress until the nuts are plucked off.

The specific electrical resistance is between 100-220 mOhm/sq, preferably between 120-200 mOhm/sq. The specific electrical resistance is measured using a conductor track of defined length and width, which was applied to a ceramic carrier and sintered (see conditions above). The layer thickness is measured after sintering, the electrical resistance of the conductor track is measured by 2-point measurement with a multimeter and then standardized to 10 μm thickness resulting in the specific electrical resistance.

The durability or lifetime of the metallic paste is >500 cycles (as determined by shock testing-40° C. for 15 min, in 7 sec to 125° C. for 15 min in 2 chambers with the respective temperature, the coated ceramic compound is transferred between the two chambers).

The increase of electrical resistance after 1000 cycles is lower than 2 Ohm.

1. A metallic paste for a ceramic substrate comprising
a metallic alloy Ni—Cu—Fe powder,
Glass powder, and
further additives.

2. The metallic paste according to claim 1, wherein it comprises a least one of Fe powder, Ni powder and Titan (IV) oxide.

3. The metallic paste according claim 1, comprising
60-80 wt % (based on the overall weight of the paste) of the Ni—Cu—Fe powder,
0.0-5 wt % (based on the overall weight of the paste) Fe powder;
0.0-5 wt % (based on the overall weight of the paste) Ni powder;
0.0-10 wt % (based on the overall weight of the paste) TiO₂;
3-15 wt % (based on the overall weight of the paste) glass powder; and
15-25 wt % of further additives, wherein the sum of all ingredients always adds up to 100 wt %.

4. The metallic paste according to claim 1, wherein the Ni—Cu—Fe alloy powder comprises of 15 to 35 wt % Ni, of 12 to 26 wt %; Cu and 45-75 wt % Fe based on the overall weight of the Ni—Cu—Fe alloy powder.

5. The metallic paste according to claim 1, wherein the average particle size d50 of the Ni—Cu—Fe powder is about 1-40 μm.

6. The metallic paste according to claim 1, wherein the average particle size d50 of the Fe powder is of 0.5 to 20 μm.

7. The metallic paste according to claim 1, wherein the glass powder comprises ZnO, SiO₂ and B₂O₃.

8. The metallic paste according to claim 1, wherein the glass powder has an average particle size d50 of 0.5 to 10 μm.

9. The metallic paste according to claim 1, wherein a solvent/diluent for example is added.

10. The metallic paste according to claim 9, wherein the solvent/diluent is one of the following: α-terpineol, butyl carbitol, butyl carbitol acetate, Texanol, octanol, 2-ethylhexanol, and mineral spirit.

11. The metallic paste according to claim 9, wherein the amount of solvent/diluent in the paste is of 0.5 to 15 wt %.

12. A method for obtaining a metallic paste according claim 1, comprising
mixing metallic alloy Ni—Cu—Fe powder, Glass powder, and SiO₂ to provide a first mixture,
adding organic additives, for example binder and dispersant to the first mixture for adjusting viscosity,
blending the mixture until a (smooth) paste is obtained.

13. (canceled)

14. A ceramic substrate with a conductor layer obtained from a metallic paste according to claim 1.

15. (canceled)

16. The metallic paste according to claim 1, wherein the metallic paste comprises less than 1.3 wt % of aluminum.

17. The metallic paste according to claim 1, wherein the further additives comprise SiO₂, a binder, a dispersant, a solvent and/or a diluent.

18. The metallic paste according to claim 17, wherein the SiO₂, is added in an amount of 0.1-1 wt % based upon the sum of weight of all ingredients which always adds up to 100 wt %.

19. The metallic paste according to claim 17, wherein the binder comprises an organic liquid comprising one or more of short (C10), middle (C50) or long (C100) chain ethers and/or esters, carboxylic acids, fatty acids, and/or cyclic and non-cyclic, linear or branched polyether or polyester, optionally with O as hetero atom in the chain.

20. The metallic paste according to claim 17, wherein the binder comprises a polymer powder dissolved in a solvent or a resin dissolved in a solvent.

21. The metallic paste according to claim 20, wherein the polymer comprises polymethacrylate(s) or nitrocellulose.

22. The metallic paste according to claim 20, wherein the resin comprises an ethyl cellulose resin, a hydroxypropyl cellulose resin, an acrylic resin, a polyester resin, a polyvinyl butyral resin, a polyvinyl alcohol resin, a rosin-modified resin, and/or an epoxy resin.
